(19) United States
(12) Patent Application Publication
(10) Pub. No.: US 2026/0028746 A1
(43) Pub. Date: Jan. 29, 2026

(54) INGOT PULLER APPARATUS INCLUDING HOTZONE COMPONENTS HAVING REFRACTORY COATINGS FOR CONTROLLING THERMAL PROPERTIES

(71) Applicant: GlobalWafers Co., Ltd., Hsinchu (TW)

(72) Inventors: Richard J. Phillips, St. Peters, MO (US); William L. Luter, St. Charles, MO (US); Carissima M. Hudson, St. Charles, MO (US)

(21) Appl. No.: 19/282,464

(22) Filed: Jul. 28, 2025

Related U.S. Application Data
(60) Provisional application No. 63/676,559, filed on Jul. 29, 2024.

(51) Int. Cl. C30B 15/14; C30B 29/06

(52) U.S. Cl. CPC C30B 15/14; C30B 29/06

(57) ABSTRACT

An ingot puller apparatus for producing a single crystal silicon ingot includes an ingot puller housing that defines a growth chamber, a crucible assembly positioned within the growth chamber for holding a silicon melt, a susceptor supporting the crucible assembly within the growth chamber, and at least one hotzone component positioned within the growth chamber. The at least one hotzone component includes a substrate having a surface emissivity and a refractory material coating applied to the substrate that modifies the surface emissivity.

### CROSS-REFERENCE TO RELATED APPLICATIONS

This application claims the benefit of U.S. Provisional Patent Application No. 63/676,559, filed Jul. 29, 2024, the entire contents of which are incorporated herein by reference.

### TECHNICAL FIELD

The field of the disclosure relates to hotzone components of an ingot puller apparatus and, in particular, to coatings for hotzone components for modifying thermal properties (e.g., emissivity) of the components.

### BACKGROUND

Single crystal silicon, which is the starting material for most processes for the fabrication of many electronic components such as semiconductor devices and solar cells, may be grown by the so-called Czochralski (CZ) process in which a silicon seed crystal is contacted with a silicon melt. The silicon seed crystal is withdrawn from the melt causing a single crystal silicon ingot suspended by the seed crystal to form. The silicon seed crystal is secured to a seed chuck that is connected to a pull cable. The pull cable supports the chuck and seed crystal (and ingot during crystal growth). The pull cable is connected to a pulling mechanism which lowers and raises the pull cable within the ingot puller apparatus.

The ingot puller apparatus includes an inner chamber, commonly or colloquially referred to as the “hotzone” of the ingot puller apparatus, that is insulated and/or includes heat shields at its perimeter to maintain the high temperature of the ingot puller apparatus within the hotzone. In some ingot puller apparatus, various graphite components are disposed within the hotzone to support the functions of the ingot puller apparatus and/or that assist in maintaining the temperature of the hotzone.

Optimal CZ crystal growth requires control of the temperature both in terms of magnitude of the temperature, but also the axial temperature profile. In many simulations encountered during crystal growth, isothermal conditions in the melt are rarely achieved, and many citations in literature discuss flow mechanisms which are related to density driven flow, where hotter regions vs. colder regions possess a different density, and thus have varying degrees of buoyancy driven flow cells. In process recipe tuning intended to obtain specific crystal properties, such as grown in point defectivity, oxygen levels, and oxygen profiles, temperatures are often influenced by power input to heaters. The spatial change of such temperature profiles is dependent on the heater response as well as transferring the emitted energy into the melt.

Known approaches for controlling temperature profiles during CZ crystal growth include using profiled heaters, short heaters, or multi-zoned heaters. These approaches are subject to the spatial layout of the heater with its associated electrical connections. Profiling also requires a machined cross-section to affect temperatures emitted by the heater by altering the local resistance causing a temperature change.

A need exists to more effectively tune the magnitude of temperature change as well as the spatial extent of the temperature change in the hotzone of ingot puller apparatus.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, an ingot puller apparatus for producing a single crystal silicon ingot includes an ingot puller housing defining a growth chamber, a crucible assembly positioned within the growth chamber for holding a silicon melt, a susceptor supporting the crucible assembly within the growth chamber, and at least one hotzone component positioned within the growth chamber. The at least one hotzone component includes a substrate having a surface emissivity, and a refractory material coating applied to the substrate that modifies the surface emissivity.

In another aspect, an ingot puller apparatus for pulling a single crystal silicon ingot from a silicon melt along a pull axis in an axial direction includes an ingot puller housing defining a growth chamber, a crucible assembly positioned within the growth chamber for holding the silicon melt, a susceptor supporting the crucible assembly within the growth chamber, at least one hotzone component positioned within the growth chamber. The at least one hotzone component has a refractory material coating applied thereto such that the at least one hotzone component has an emissivity profile that varies along the axial direction.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic cross-section side view of an ingot pulling apparatus or ingot puller during growth of an ingot of semiconductor material.

FIG. 2A illustrates side and front views of an example hotzone component without a refractory coating, along with the resulting temperature profile of the hotzone component when configured as an emitter.

FIG. 2B illustrates side and front views of the example hotzone component of FIG. 2A with an example refractory coating, along with the resulting temperature profile of the hotzone component when configured as an emitter.

FIG. 2C illustrates side and front views of the example hotzone component of FIG. 2A with an example refractory coating applied to only a portion of the hotzone component, along with the resulting temperature profile of the hotzone component when configured as an emitter.

FIG. 2D illustrates side and front views of the example hotzone component of FIG. 2A with an example refractory coating applied as a continuous coating to a lower portion of the hotzone component and as a patterned coating along an intermediate portion of the hotzone component, along with the resulting temperature profile of the hotzone component when configured as an emitter.

Corresponding reference characters indicate corresponding parts throughout the drawings.

### DETAILED DESCRIPTION

Provisions of the present disclosure relate to ingot puller apparatus having one or more hotzone components that are coated or otherwise covered with a refractory material to control a surface emissivity thereof.

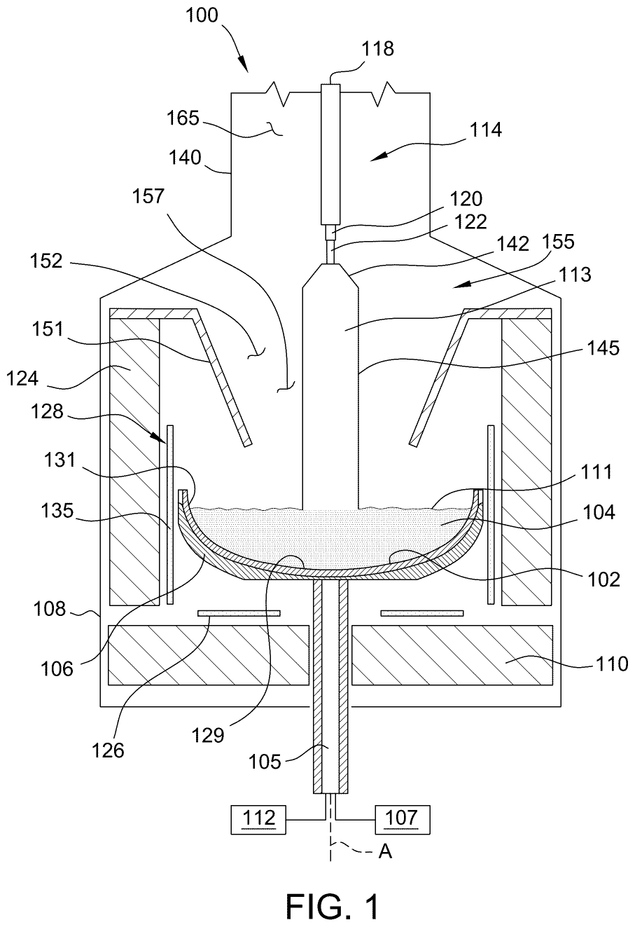

An example ingot puller apparatus (or more simply “ingot puller”) is indicated generally at 100 in FIG. 1. The ingot puller 100 is used to produce single crystal (i.e., monocrystalline) ingots 113 of semiconductor or solar-grade material such as, for example, single crystal silicon ingots. Although the ingot puller 100 is described herein primarily with reference to silicon and single crystal silicon ingots, it is understood that the ingot puller 100 is suitable for use with other types of semiconductor materials, and may be used to produce single crystal semiconductor ingots other than single crystal silicon ingots. In some embodiments, the ingot is grown by the so-called Czochralski (CZ) process in which the ingot is withdrawn from a melt 104 of silicon or other semiconductor material held within a crucible 102 of the crystal puller 100. In some embodiments, the ingot is grown by a batch CZ process in which polycrystalline silicon is charged to the crucible 102 in an amount sufficient to grow one ingot, such that the crucible 102 is essentially depleted of silicon melt 104 after the growth of the one ingot. In other embodiments, the ingot is grown by a continuous CZ (CCZ) process in which polycrystalline silicon is continually or periodically added to crucible 102 to replenish silicon melt 104 during the growth process. The CCZ process facilitates growth of multiple ingots pulled from a single melt 104. Embodiments of the subject matter described herein are not limited to a particular crystal growth process, however.

The ingot puller apparatus 100 includes an ingot puller housing 108 that defines a growth chamber 152 for pulling a silicon ingot from the silicon melt 104 along a pull axis A. The growth chamber 152 includes two portions-a lower growth chamber 155 (or simply “lower chamber”) and an upper growth chamber 165 (or simply “upper chamber,” also referred to as a pull chamber) disposed above the lower growth chamber 155 and having a smaller transverse dimension than the lower growth chamber 155. The lower growth chamber 155 has an upper wall transitioning from the lower growth chamber 155 to the upper growth chamber 165. The ingot puller 100 may also include one or more inlet ports and outlet ports (not labeled in FIG. 1) to introduce and remove a process gas to and from the ingot puller 100 during crystal growth.

The crucible 102 (also referred to as a crucible assembly) is positioned within the growth chamber 152 (specifically, the lower growth chamber 155) and contains the silicon melt 104 from which a single crystal silicon ingot is drawn. The crucible 102 may be made of quartz or fused silica, which has a high melting point and thermal stability and is generally non-reactive with molten silicon in the melt 104. It should be understood that the crucible 102 may be made from other materials in addition to quartz without departing from the scope of the present disclosure. For example, the quartz crucible 102 may be made from a composite material that includes silica and an additional material, for example, silicon nitride or silicon carbide.

The silicon melt 104 is obtained by melting polycrystalline silicon charged to the crucible 102. In continuous systems, a feed system (not shown) is used for feeding solid feedstock material into the crucible assembly 102 and/or the melt 104.

The crucible 102 is positioned within and supported by a susceptor 106 that is in turn supported by a rotatable shaft 105. The illustrated crucible 102 includes a sidewall 131 and floor 129 that rests on the susceptor 106.

The susceptor 106 and rotatable shaft 105 facilitate rotation of the crucible 102 about a central longitudinal or pull axis A of the ingot puller 100. The susceptor 106, crucible assembly 102, shaft 105, and ingot 113 are all aligned (i.e., have a common longitudinal axis) along the longitudinal axis A. The longitudinal axis A defines an axial direction of the ingot puller apparatus 100 along which the ingot 113 is pulled during an ingot growth process.

A pulling mechanism 114 is provided within the ingot puller apparatus 100 for growing and pulling an ingot 113 from the melt 104. The pulling mechanism 114 includes a pull cable 118, a seed holder or chuck 120 coupled to one end of the pull cable 118, and a seed crystal 122 coupled to the chuck 120 for initiating crystal growth. One end of the pull cable 118 is connected to a pulley (not shown) or a drum (not shown) of the pulling mechanism 114 and the other end is connected to the chuck 120 that holds the seed crystal 122. The pulling mechanism 114 includes a motor that rotates the pulley or drum.

In operation, the seed crystal 122 is lowered to contact the surface 111 of the melt 104. The pulling mechanism 114 is operated to cause the seed crystal 122 to rise. This causes a single crystal ingot 113 to be pulled from the melt 104.

During heating and crystal pulling, a crucible drive unit 107 (e.g., a motor) rotates the crucible assembly 102 and susceptor 106. A lift mechanism 112 raises and lowers the crucible assembly 102 along the pull axis A during the growth process. For example, the crucible assembly 102 may be at a lowest position (near a bottom heater 126) in which a charge of solid-phase silicon previously added to the crucible assembly 102 is melted. Crystal growth commences by contacting the melt 104 with the seed crystal 122 and lifting the seed crystal 122 by the pulling mechanism 114.

A crystal drive unit (not shown) may also rotate the pulling cable 118 and ingot 113 in a direction opposite the direction in which the crucible drive unit 107 rotates the crucible assembly 102 (e.g., counter-rotation). In embodiments using iso-rotation, the crystal drive unit may rotate the pulling cable 118 in the same direction in which crucible drive unit rotates the crucible assembly 102.

A heating system 128 (e.g., one or more electrical resistance heaters) is disposed externally to the crucible assembly 102 and surrounds the susceptor 106 and crucible 102 to supply heat by conduction through the susceptor 106 and crucible 102 for melting the silicon charge to produce the melt 104 and/or maintaining the melt 104 in a molten state. The heater system 128 may also extend below the susceptor 106 and crucible 102. The heating system 128 of the example ingot puller apparatus 100 includes a bottom heater 126 and a side heater 135. The bottom heater 126 is disposed below the crucible floor 129. The crucible assembly 102 may be moved to be in relatively close proximity to the bottom heater 126 to melt the solid silicon charged to the crucible assembly 102.

The side heater 135 and the susceptor 106 encircle the crucible assembly 102 to maintain the temperature of the melt 104 during crystal growth. The side heater 135 is disposed radially outward of the crucible sidewall 131 as the crucible assembly 102 travels up and down the pull axis A. The side heater 135 and bottom heater 126 may be any type of heater that allows the side heater 135 and bottom heater 126 to operate as described herein. In some embodiments, the heaters 135, 126 are electrical resistance heaters.

The heating system 128 is controlled by a control system (not shown) so that the temperature of the melt 104 is precisely controlled throughout the pulling process. For example, the controller may control electric current provided to the heating system 128 to control the amount of thermal energy supplied by the heating system 128. The controller may control the heating system 128 so that the temperature of the melt 104 is maintained above about the melting temperature of silicon (e.g., about 1412° C.). For example, the melt 104 may be heated to a temperature of at least about 1425° C., at least about 1450° C. or even at least about 1500° C.

Insulation surrounding the heating system 128 may reduce the amount of heat lost through the housing 108. For example, the illustrated ingot puller apparatus 100 includes bottom insulation 110 and side insulation 124 to retain heat within the puller apparatus 100.

The ingot puller 100 may also include a heat shield or reflector assembly above the surface of the melt 104 for shielding the ingot 113 from the heat of the crucible 102, for example, to increase the axial temperature gradient at the solid-melt interface. For example, the ingot puller apparatus 100 of the illustrated embodiment includes a reflector assembly 151 that defines a central opening 157 through which the single crystal silicon ingot 113 is pulled during ingot growth.

According to the Czochralski single crystal growth process, a quantity of solid-phase silicon such as polycrystalline silicon, or “polysilicon,” is initially charged to the crucible assembly 102. The semiconductor or solar-grade solid silicon that is introduced into the crucible assembly 102 is melted by heat provided from one or more heating assemblies. Once the melt 104 is fully formed, the seed crystal 122 is lowered and contacted with the surface 111 of the melt 104. The pulling mechanism 114 is operated to pull the seed crystal 122 from the melt 104. The resulting ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

A process gas (e.g., argon) is introduced through one or more inlet ports (not shown) into the lower growth chamber 155 and the upper growth chamber 165, and is withdrawn through one or more outlet ports (not shown). The process gas creates an atmosphere within the housing, and the melt and the atmosphere form a melt-gas interface.

The crystal growth process may be a batch process in which solid silicon is initially added to the crucible assembly 102 to form a silicon melt without additional solid-silicon being added to the crucible assembly 102 during crystal growth. In other embodiments, the crystal growth process is a continuous Czochralski process in which an amount of silicon is added to the crucible assembly during ingot growth.

The illustrated ingot puller apparatus 100 is an example and any ingot puller apparatus 100 that includes one or more hotzone components that are coated with a refractory material may be used unless stated otherwise.

The hotzone of the ingot puller apparatus 100 generally refers to the area enclosed within the lower growth chamber 155 and that is insulated and/or includes heat shields at its perimeter to maintain the high temperature of the ingot puller apparatus 100 within the hotzone. Example components within the hotzone, which are suitably made of graphite in some embodiments, include, for example and without limitation, reflector assemblies (e.g., reflector assembly 151), heaters (e.g., bottom heater 126 and/or side heater 135), insulation (e.g., bottom insulation 110 and side insulation 124), exhaust ports, and reflector supports.

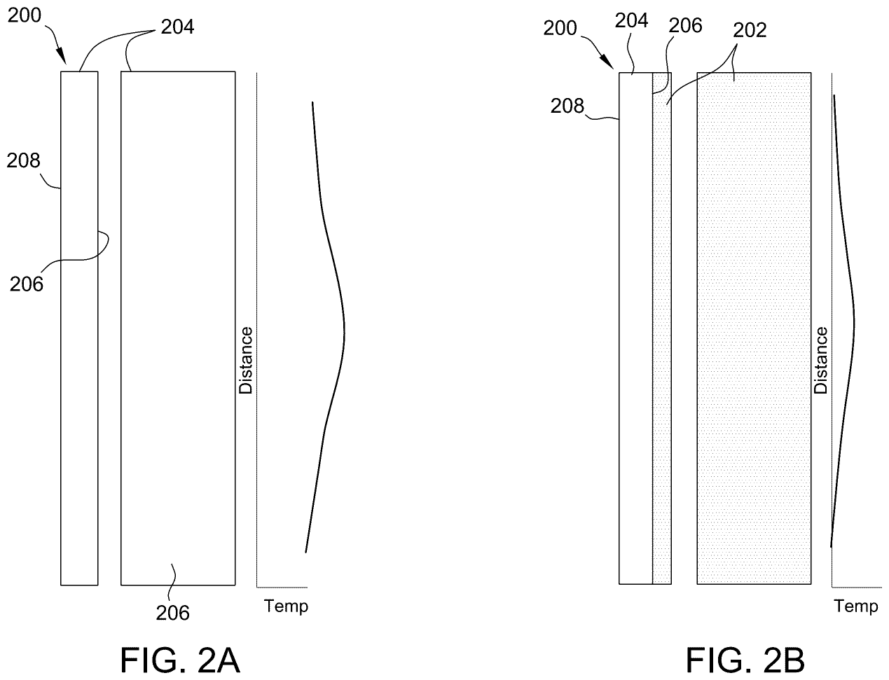

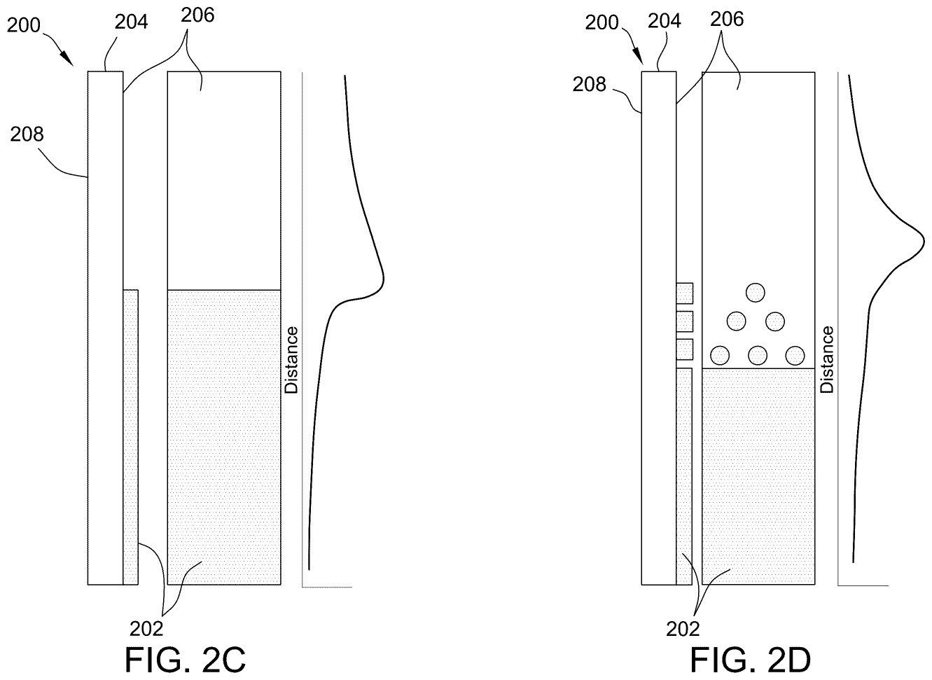

In accordance with the present disclosure, and with additional reference to FIGS. 2A and 2B, one or more of the hotzone components positioned within the growth chamber 152 of the ingot puller apparatus 100 can include a refractory material coating 202 applied thereto that modifies the surface emissivity or emissivity profile of the hotzone component. FIG. 2A illustrates an example hotzone component 200 without the refractory material coating 202, whereas FIG. 2B illustrates the hotzone component 200 with the refractory material coating 202 applied thereto.

As shown in FIGS. 2A and 2B, the example hotzone component includes a substrate 204 to which the refractory material coating 202 is applied (FIG. 2B). The substrate 204 of the hotzone component 200 can be part of a main body of the hotzone component 200, for example. The substrate 204 has a surface emissivity based on the material from which the substrate 204 is made. Suitable materials from which the hotzone component 200 and the substrate 204 may be constructed include, for example and without limitation, graphite, quartz, pure refractory metals (e.g., molybdenum, tungsten, etc.), ceramics (e.g., SiC and SiN) and combinations thereof. Graphite has a relatively high emissivity, typically reported as within the range of 0.7-0.9, or within the range of 0.8-0.83, even at operating temperatures within the ingot puller (e.g., 1500° C. or higher). In some embodiments, the substrate 204 has a surface emissivity at a temperature of 1500° C. within the range of 0.7-0.9, within the range of 0.7-0.85, within the range of 0.8-0.95, within the range of 0.8-0.9, or within the range of 0.8-0.83.

The refractory coatings of the present disclosure generally have or yield an emissivity lower than the surface emissivity of the hotzone component substrate 204 to which they are applied (e.g., graphite). The refractory coatings of the present disclosure can thereby be used to more effectively tune the magnitude of temperature change as well as the spatial extent of temperature change or the emissivity profile of the hotzone component 200. In suitable embodiments, the refractory coatings have an emissivity lower than graphite, or another material used for the hotzone component(s), whereby the coatings are applied either fully or selectively to the hotzone component of interest. In this way, temperature or emissivity profiles may be achieved that may result in improved properties in the crystal ingot, as well as avoid extensive unstable conditions in the melt, such as freezing or icing during crystal growth.

The refractory material coating 202 is suitably made of one or more materials that exhibit a lower emissivity than the surface emissivity of the hotzone component 200 (e.g., graphite), while being able to withstand the temperatures of the CZ growth process. Examples of suitable materials include, for example and without limitation, molybdenum, tantalum, tantalum oxide (Ta₂O₃), hafnium, hafnia (hafnium oxide (HfO₂)), yttria (yttrium oxide (Y₂O₃)) and zirconia (zirconium dioxide (ZrO₂)). In some embodiments, for example, the refractory material coating 202 includes molybdenum, tantalum, hafnium, hafnia, hafnium, hafnia, yttria, zirconia, or a combination of two or more thereof.

In some embodiments, the surface emissivity of the refractory material coating 202 at a temperature of 1500° C. is less than 0.8, less than 0.6, less than 0.5, less than 0.4, within the range of 0.1 to 0.8, within the range of 0.1 to 0.6, within the range of 0.2 to 0.6, or within the range of 0.2 to 0.4. For example, tests in a high temperature vacuum furnace at crystal growth temperatures such as 1500° C. or higher, indicate an emissivity in the range of 0.2 to 0.4 for materials such as molybdenum, tantalum, and hafnium. Oxide coatings (e.g., oxides of the above mentioned refractory metals (Mo, Ta, Hf), ZrO₂, etc.) offer similar potential to alter the emissivity below that of graphite.

In one example, the hotzone component 200 is configured as an emitter for active heat emission (e.g., as a heater). In such embodiments, a surface with an emissivity lower than that of the hotzone component substrate 204 (e.g., graphite) would yield a lower radiant temperature on a surrounding surface when conduction is dominated by radiation. For an application such as a heater (e.g., the heater 126 and/or 135), an axially-varying or non-uniform axially application of the coating 202 would render the heater to emit a lower temperature on a receiving body that is being heated compared to that same body and heater emitting from a non-coated graphite surface (e.g., the hotzone component shown in FIG. 2A). In this sense, the coating 202 can render the heater to have an engineered axial temperature or emissivity profile that is different than the uncoated hotzone component 200 (e.g., uncoated graphite). This would be facilitated by coating selected surfaces on the hotzone component substrate 204 which would result in the altered temperature or emissivity profile. In this context, “axially-varying” or “axially non-uniform” refers to a non-uniform application of the coating 202 in the axial direction of the ingot puller 100 (i.e., the direction in which the ingot 113 is pulled from the melt 104). For example, the coating may be applied only to an axially lower portion of the hotzone component 200 or only to an axially upper portion of the hotzone component 200 to create an axially non-symmetric or axially asymmetric emissivity profile.

In another example, the hotzone component 200 is configured as a passive or non-active heating component. In this case, the removal of energy from the emitter onto the passive surface is reduced. Such applications can be used, for example and without limitation, on reflective surfaces above the melt, such as a surfaces of the reflector assembly 151. Additionally or alternatively, the refractory material coating 202 can be applied to insulation packs (e.g., the insulator 110 and/or 124) to reduce heat loss into a cooling (e.g., water) jacket (not shown).

As shown in FIGS. 2A and 2B, the hotzone component 200 of the illustrated embodiment includes a first surface 206 and a second surface 208 positioned opposite the first surface 206. The refractory material coating 202 can be applied to one or both of the first surface 206 and the second surface 208. In some embodiments, the first surface 206 is a surface that is oriented towards or faces towards the pull axis A of the ingot puller apparatus 100. For example, the first surface 206 may face towards and/or be aligned with the crucible assembly 102 of the ingot puller apparatus 100 or the melt 104 contained therein. Further, the second surface 208 can be oriented away or face away from the pull axis A of the ingot puller 100, and face away from the crucible assembly 102 or the melt 104. In such embodiments, the refractory material coating 202 can be applied only to the first surface 206 (i.e., the surface facing the crucible and/or the melt), only to the second surface 208 (i.e., the surface facing away from the crucible and/or the melt), or to both the first surface 206 and the second surface 208. For example, where the hotzone component 200 is a heater (e.g., heater 126 and/or 135) or insulation (e.g., insulation 110 and/or 124), the refractory material coating 202 may be applied only to the first surface 206 (i.e., the surface facing the crucible and/or the melt). As another example, where the hotzone component 200 is a reflector assembly (e.g., reflector assembly 151), the refractory material coating 202 may be applied only to the first surface 206, only to the second surface 208 (i.e., the surface facing away from the crucible and/or the melt), or to both the first surface 206 and the second surface 208.

Because the coatings are applied to the surface of hotzone components, the coatings can be applied fully along the face of a member, partially or terminated at specific locations. In particular, in any of the foregoing embodiments, the coating 202 can be applied (e.g., to the first surface 206 and/or the second surface 208) continuously or intermittently or patterned to design a desired profile in a spatial extent. In some embodiments, for example, the refractory material coating 202 is a continuous coating that covers an entirety of the first surface 206 and/or the second surface 208. In FIG. 2B, for example, the refractory material coating 202 is a continuous coating that covers an entirety of the first surface 206 (i.e., the crucible-facing surface). In other embodiments, the refractory material coating 202 is a continuous coating that covers only a portion of the first surface 206 and/or the second surface 208 (e.g., only an axial upper portion or only an axial lower portion). In FIG. 2C, for example, the refractory material coating 202 is a continuous coating that covers only a portion of the first surface 206 (i.e., the crucible-facing surface). In yet other embodiments, the refractory material coating 202 is a non-continuous coating (e.g., a patterned or intermittent coating) applied to only a portion of the first surface 206 and/or the second surface 208. In some embodiments, for example, the refractory material coating 202 is a patterned coating that has a repeating pattern applied to the first surface 206 and/or the second surface 208. FIG. 2D, for example, illustrates the refractory material coating 202 applied as a continuous coating along an axial lower portion of the hotzone component 200 and as a patterned coating with a repeating circular pattern along an axial intermediate portion of the hotzone component 200. Because of the change in the emissivity and view of the coated or partially coated surface, the temperature output can be tuned to achieve a desired axially rate of change in temperature depending on targeted crystal properties. It should be understood that the example coatings illustrated in FIGS. 2B-2D are exemplary only, and that refractory material coatings may be applied in any other suitable manner to produce a desired temperature or emissivity profile of an underlying hotzone component. For example, in the examples of FIGS. 2C and 2D, the sections that are coated or patterned can be inverted, with the upper sections being coated, resulting in the corresponding inversion of the temperature profiles. As another example, the coatings 202 illustrated in FIGS. 2B-2D can be applied to the opposing second surface 208 instead of or in addition to the first surface 206.

FIGS. 2A-2D also illustrate example resulting temperature profiles of the full, partial, and patterned coatings 202 when the hotzone component 200 is configured as an emitter, specifically as a heater. FIG. 2A, for example, illustrates an example temperature profile from an uncoated heater. FIG. 2B illustrates an example temperature profile when the refractory material coating 202 is applied as a continuous coating that covers an entirety of the first surface 206. In this example, the temperature profile depicts a temperature reduction as compared to the uncoated case of FIG. 2A. FIG. 2C illustrates an example temperature profile when the refractory material coating 202 is applied as a continuous coating that covers only a portion of the first surface 206 of the hotzone component 200, specifically an axial lower portion of the hotzone component 200. In this example, the temperature profile depicts a distinctive transition across the coated/uncoated region. FIG. 2D illustrates an example temperature profile when the refractory material coating 202 is applied as a continuous coating along an axial lower portion of the hotzone component 200 and as a patterned coating with a repeating circular pattern along an axial intermediate portion of the hotzone component 200. As compared to the example temperature profiles of FIGS. 2A-2C, the peak temperature of the example temperature profile in FIG. 2D is shifted upward.

Use of hotzone components including the refractory material coatings of the present disclosure (e.g., one or more of the hotzone components 200 pictured in FIGS. 2B-2D) with a crucible (e.g., the crucible 102) having a melt (e.g., the melt 104) as a receiver of the energy distribution makes it is possible to adjust the melt temperature profile with similar axial asymmetry as that of the hotzone component, while affecting corresponding melt flows, which can alter the crystal properties.

As noted above, in other embodiments the hotzone component 200 can be configured as a passive or non-active heating component (e.g., an insulator or reflector). In such embodiments, the coatings can be applied in any suitable manner as described herein (e.g., fully, patterned, transitioned, etc.) as desired to obtain a corresponding desired temperature effect on a receiving body from an energy emitter. When the hotzone component 200 is configured as a passive element, the receiving body (i.e., a body receiving energy reflected by the hotzone component 200) would experience a higher temperature on a surface section of the receiving body aligned with a coated surface of the hotzone component 200 and a lower temperature on a surface section of the receiving body aligned with an uncoated surface. This is because the surfaces with the lower emissivity coating would absorb less energy and act more as a high temperature reflector or mirror of the energy. In the case of coated insulation placed between a cooling (e.g., water) jacket of a puller and its heating element, a fully coated case can be implemented to reduce heat loss into the cooling jacket.

Further, the coatings of the present disclosure can help prevent or reduce degradation of hotzone components by preventing or inhibiting porosity alteration through reaction with the ambient environment. In the case of an insulator, for example, if the coating were inert to the ambient environment, the insulation properties of the insulator would not degrade by porosity alteration through reaction with the ambient. More specifically, when graphite is subjected to the operating conditions of a CZ ingot puller, the graphite can react with Sio (g) or SiO. (s) (where it is in contact with SiO.) and can produce CO (g) or SiC(s), depending on the reaction gas concentration and temperature. The CO (g) can cause a direct increase in the porosity of the graphite, and the SiC(s) can cause physical degradation, particularly when thermally cycled, which is not uncommon for CZ ingot pullers. By having an inert coating on a surface of the hotzone component that does not react with the ambient environment, or reacts at slower speed with the ambient environment, the production of CO or SiC can be reduced, thereby reducing porosity alteration. Thus, in cases where an inert coating is used on a porous graphitic insulation hotzone component, the porosity and structural integrity and insulation properties of the insulation hotzone component can be preserved.

The refractory coatings of the present disclosure can be applied to the hotzone components using any suitable coating application technique that allows the hotzone components to function as described herein. In some embodiments, for example, the refractory coatings or portions of the refractory coatings are applied by plasma spraying, thermal spraying, or a combination thereof. In another example, the refractory coatings or portions of the refractory coatings are applied by chemical vapor deposition.

In addition to, or as an alternative to, the above-described refractory coatings, a refractory sheet may be applied to one or more hotzone components to modify the emissivity thereof in the same or similar matter as the refractory material coatings. For example, the refractory material coating 202 illustrated in FIG. 2B may instead be implemented as a refractory sheet that is affixed or connected to the hotzone component 200 using any suitable connection means. The refractory sheet may be formed from the same materials as the refractory coatings described herein, including, for example and without limitation, molybdenum, tantalum, hafnium, hafnia, yttria and zirconia.

The refractory sheet may be implemented as a single sheet or as a series of multiple thinner layers (e.g., a laminated sheet). In either implementation, the combined or cumulative thickness of the refractory sheet may be any suitable thickness that enables the hotzone components to function as described herein. In some embodiments, for example, the combined or cumulative thickness of the refractory sheet is less than 5 mm, less than 3 mm, less than 1 mm, less than 0.5 mm, in the range of 0.1 mm and 1.0 mm, or in the range of 0.1 mm and 0.5 mm. Additionally, in some embodiments, the refractory sheet may have a non-uniform thickness so as to conform to the shape of a hotzone component to which it is applied.

The refractory sheet may be implemented as a continuous, sold sheet, similar to the continuous coating illustrated in FIG. 2B, or the refractory sheet can be perforated to grade the transmissive/conductive properties (e.g., axially) as desired.

Suitable hotzone components to which the refractory material coatings and/or sheets of the present disclosure may be applied include, for example and without limitation, heaters (e.g., heater 126 and/or 135), insulation (e.g., insulation 110 and/or 124), reflector assemblies (e.g., reflector assembly 151, or other reflectors, including cylindrical tube-like reflectors, non-axially-symmetric reflectors, elliptical reflectors, etc.), exhaust ports, and reflector supports.

Embodiments of the present disclosure provide improved control of temperature change magnitude and spatial extent by using a heater as an energy emitter, or a reflector or insulator, with a low emissivity coating or sheet to alter the emitted or reflected energy to create a desired temperature profile in a CZ crystal puller. The coating or sheet can be applied continuously, patterned, or perforated depending on the application and whether the substrate is actively heated or passively reflecting. The embodiments described herein can be applied in batch CZ growth processes or continuous CZ growth processes.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An ingot puller apparatus for producing a single crystal silicon ingot, the ingot puller apparatus comprising:
an ingot puller housing defining a growth chamber;
a crucible assembly positioned within the growth chamber for holding a silicon melt;
a susceptor supporting the crucible assembly within the growth chamber; and
at least one hotzone component positioned within the growth chamber, wherein the at least one hotzone component includes:
a substrate having a surface emissivity; and
a refractory material coating applied to the substrate that modifies the surface emissivity.

2. The ingot puller apparatus of claim 1, wherein the refractory material coating includes molybdenum, tantalum, tantalum oxide, hafnium, hafnia, yttria, zirconia, or a combination of two or more thereof.

3. The ingot puller apparatus of claim 1, wherein the substrate is graphite.

4. The ingot puller apparatus of claim 1, wherein the refractory material coating has an emissivity less than the surface emissivity of the substrate.

5. The ingot puller apparatus of claim 4, wherein the surface emissivity of the substrate at a temperature of 1500° C. is within the range of 0.7 to 0.9.

6. The ingot puller apparatus of claim 4, wherein the surface emissivity of the refractory material coating at a temperature of 1500° C. is within the range of 0.2 to 0.4.

7. The ingot puller apparatus of claim 1, wherein the at least one hotzone component includes a first surface that faces towards a pull axis of the ingot puller apparatus, wherein the refractory material coating is applied to the first surface.

8. The ingot puller apparatus of claim 7, wherein the refractory material coating is a continuous coating that covers an entirety of the first surface.

9. The ingot puller apparatus of claim 7, wherein the refractory material coating is a continuous coating that covers only a portion of the first surface.

10. The ingot puller apparatus of claim 7, wherein the refractory material coating is a non-continuous coating applied to only a portion of the first surface.

11. The ingot puller apparatus of claim 10, wherein the refractory material coating is a patterned coating having a repeating pattern applied to the first surface.

12. The ingot puller apparatus of claim 7, wherein the at least one hotzone component includes a second surface opposite the first surface that faces away from the pull axis of the ingot puller, wherein the refractory material coating is applied to the second surface.

13. The ingot puller apparatus of claim 1, wherein the at least one hotzone component comprises one or more of:
a heater assembly disposed external to the crucible assembly;
insulation disposed along one or more inner surfaces of the ingot puller housing; or
a reflector assembly defining an opening for receiving the ingot as the ingot is pulled through the reflector assembly.

14. The ingot puller apparatus of claim 1, wherein the at least one hotzone component comprises a heater assembly disposed external to the crucible assembly.

15. The ingot puller apparatus of claim 1, wherein the at least one hotzone component comprises insulation disposed along one or more inner surfaces of the ingot puller housing.

16. The ingot puller apparatus of claim 1, wherein the at least one hotzone component comprises a reflector assembly defining an opening for receiving the ingot as the ingot is pulled through the reflector assembly.

17. An ingot puller apparatus for pulling a single crystal silicon ingot from a silicon melt, wherein the ingot is pulled along a pull axis in an axial direction, the ingot puller apparatus comprising:
an ingot puller housing defining a growth chamber;
a crucible assembly positioned within the growth chamber for holding the silicon melt;
a susceptor supporting the crucible assembly within the growth chamber; and
at least one hotzone component positioned within the growth chamber and having a refractory material coating applied thereto such that the at least one hotzone component has an emissivity profile that varies along the axial direction.

18. The ingot puller apparatus of claim 17, wherein the refractory material coating includes molybdenum, tantalum, tantalum oxide, hafnium, hafnia, yttria, zirconia, or a combination of two or more thereof.

19. The ingot puller apparatus of claim 17, wherein the at least one hotzone component includes a substrate having a surface emissivity, wherein the refractory material coating is applied to the substrate to produce the emissivity profile that varies along the axial direction.

20. The ingot puller apparatus of claim 19, wherein the substrate is graphite, and wherein the refractory material coating has an emissivity less than the surface emissivity of the substrate.
